(19) United States
(12) Patent Application Publication
(10) Pub. No.: US 2006/0138613 A1
(43) Pub. Date: Jun. 29, 2006

(54) INTEGRATED CIRCUIT PACKAGE WITH INNER GROUND LAYER

(76) Inventor: HENRY TIN-HANG YUNG, Hsin-Chu County (TW)

Correspondence Address: NORTH AMERICA INTELLECTUAL PROPERTY CORPORATION, P.O. BOX 506, MERRIFIELD, VA, 22116, US

(21) Appl. No.: 11/163,939

(22) Filed: Nov. 4, 2005

Related U.S. Application Data
(60) Provisional application No. 60/593,095, filed on Dec. 9, 2004.

(51) Int. Cl. H01L 23/495

(52) U.S. Cl. 257/666

(57) ABSTRACT

An integrated circuit package includes a lead frame having a plurality of leads and a metal layer; an integrated circuit die having a plurality of power-level bond pads; a plurality of first bond wires electrically connected between the power-level bond pads and the metal layer, respectively; and a second bond wire electrically connected between the metal layer and a lead of the lead frame.

### CROSS REFERENCE TO RELATED APPLICATIONS

This application claims the benefit of U.S. Provisional Application No. 60/593,095, filed Dec. 09, 2004, entitled “Integrated Circuit Package with a Monitor-Controller” and included herein by reference.

### BACKGROUND OF THE INVENTION

1. Field of the Invention

The present invention relates to an integrated circuit package, and more particularly to an integrated circuit package and related method of bonding a plurality of ground-voltage bond pads of an integrated circuit die to an inner ground layer disposed on a lead frame.

2. Description of the Prior Art

Lead frames are commonly used in semiconductor packages. Please refer to FIG. 1, which is a diagram illustrating a conventional integrated circuit package 100. The integrated circuit package 100 includes an integrated circuit die 102 mounted on a lead frame 112. The integrated circuit die 102 comprises a plurality of bond pads 104 that are respectively electrically connected to an inner portion of the leads 106 of the lead frame 112 through a plurality of bond wires 110. The integrated circuit die 102, also called a semiconductor chip, the inner portion of the leads 106 and the bond wires 110 are encapsulated into the integrated circuit package 100. After encapsulation, a border or frame on the outer portion of the lead frame 112 is cut to separate outer portions of the leads 106, thereby forming connecting pins or surface mount contacts used to electrically connect the electronic circuitry in the integrated circuit die 102 with externally arranged electronic components mounted on a printed circuit board. A printed circuit board used in an application system, e.g. a computer or television monitor, needs a ground layer formed by a plate copper layer. The ground layer of the printed circuit board is used to reduce noise interference and allow a higher sink current to the voltage ground level. The ground layer generally has a low impedance characteristic because of the use of high conductive metal, like copper, silver, gold or aluminum. However, since forming a ground layer in a printed circuit board requires a large area on at least one side of the printed circuit board, in order to reduce the size of the printed circuit board, a multi-layer printed circuit board is widely used to mount circuit components on one or two sides and form a ground layer on the other side or in an inner layer.

Please refer to FIG. 2, which is a cross-sectional view of the integrated circuit package 100 mounted on a printed circuit board 202. The printed circuit board 202 has upper plane conductive layer 104 and bottom plane conductive board 204 connected to two leads 106 of the integrated circuit package 100 by the use of conductive through-holes (vias) 205. The conventional printed circuit board 202 requires a large-area plane conductive layer 204 to serve as a ground layer for reducing noise interference, which increases cost of the printed circuit board.

During manufacture of the integrated circuit package 100, a specific configuration may be used to place appropriate jumper connections between bond pads 104 and the inner portion of the leads 106. Typically, various combinations of bond pads 104 on the integrated circuit die 102 are connected together through a common connection to the inner portion of the leads 106 of the lead frame 112. However, such specific interconnections in the integrated circuit package 100 become problematic when the bond pads 104 are separated in opposite sides of the integrated circuit die 102. Making more than one wire-bonding connection to a lead may not be practical in smaller and more densely packaged integrated circuits. Even when possible, such connections may increase bonding cost and cause various other manufacturing problems.

In addition, the functionality of the integrated circuit is becoming more and more complicated nowadays, increasing the number of external connection pins of the integrated circuit package. As the pin count is increased, the cost of packaging an integrated circuit die is increased accordingly. Therefore, how to connect a plurality of bond pads together without sacrificing the package size and the package cost becomes an important issue for the manufacturers and designers.

### SUMMARY OF THE INVENTION

The present invention overcomes the above-identified problems as well as other shortcomings and deficiencies of existing technologies by providing an integrated circuit package and related method of bonding a plurality of ground-voltage pads on an integrated circuit die to an inner ground layer disposed on a lead frame.

According to an exemplary embodiment of the invention, an integrated circuit package comprises: a lead frame having a plurality of leads and a metal layer; an integrated circuit die having a plurality of power-level bond pads; a plurality of first bond wires electrically connected between the power-level bond pads and the metal layer, respectively; and a second bond wire electrically connected between the metal layer and a lead of the lead frame.

According to an exemplary embodiment of the invention, a method of packaging an integrated circuit die is disclosed. The integrated circuit die has a plurality of power-level bond pads. The method comprises providing a lead frame with a plurality of leads and a metal layer; mounting the integrated circuit die on the lead frame; electrically connecting the power-level bond pads to the metal layer respectively; and electrically connecting the metal layer to a lead of the lead frame.

The integrated circuit package of the present invention makes use of a metal layer, like copper, silver, gold or aluminum, to create a common interconnection ground area therein to reduce unwanted noise interference. Due to the metal layer serving as a ground layer being disposed within the integrated circuit package, a printed circuit board can dispose of a ground layer originally formed thereon. In addition, the integrated circuit package requires only a single external ground pin, which saves the cost of forming pins used to connect a printed circuit board. Furthermore, the cost of a printed circuit board is reduced because the integrated circuit package of the present invention can be applied to a single-layer printed circuit board.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram illustrating a conventional integrated circuit package.

FIG. 2 is a cross-sectional view of the integrated circuit package shown in FIG. 1 mounted on a printed circuit board.

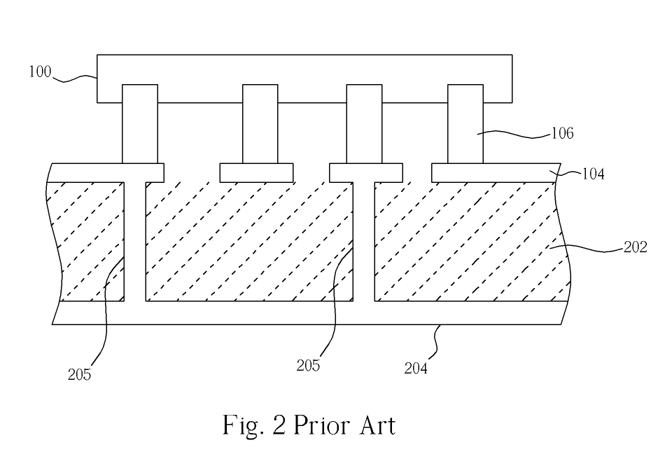

FIG. 3 is a diagram illustrating an integrated circuit package according to an embodiment of the present invention.

FIG. 4 is a side view of the integrated circuit package shown in FIG. 3.

### DETAILED DESCRIPTION

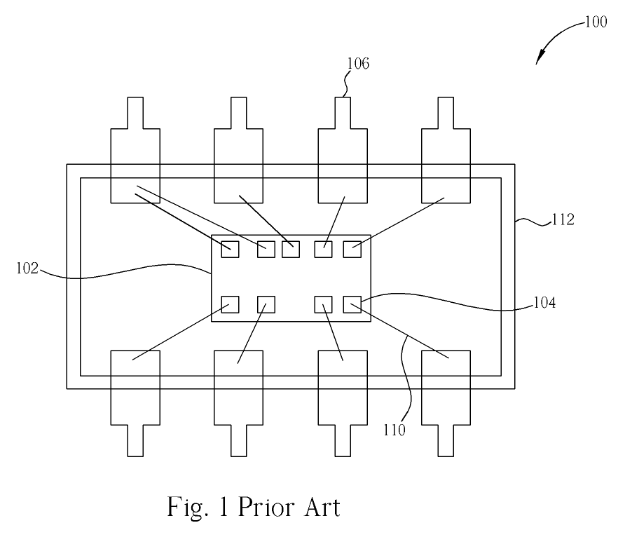

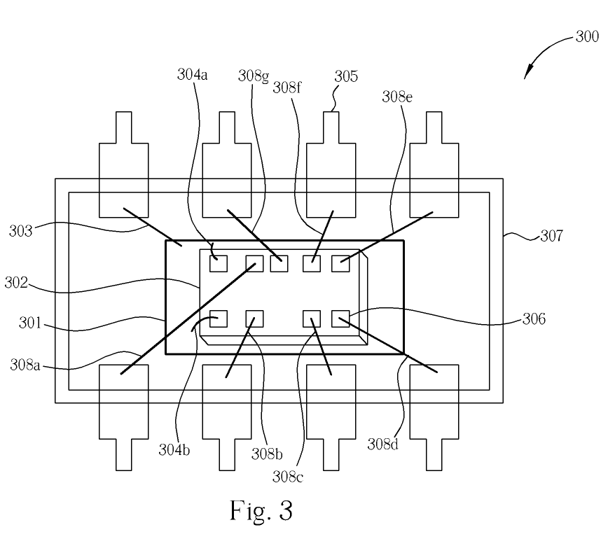

The drawings are for purposes of illustrating embodiments of the present invention only, and the circuit configurations shown in the drawings are not meant to be taken as limitations to the present invention. Please refer to FIG. 3, which is a diagram illustrating an integrated circuit package 300 according to an embodiment of the present invention. In this embodiment, the integrated circuit package 300 comprises an integrated circuit die 302 (e.g., a display controller chip, a network controller chip, a RF communication chip etc.) mounted on a metal layer 301 serving as a ground layer. The integrated circuit die 302 has a plurality of bond pads 306, where two bond pads 306 are connected to the metal layer 301 by bond wires 304a, 304b and remaining bond pads 306 are connected to corresponding leads 305 of a lead frame 307 through bond wires 308a-308g. In addition, an inner portion of a lead 305 is connected to the metal layer 301 by a bond wire 303. The key difference between the integrated circuit package 300 shown in FIG. 3 and the integrated circuit package 100 shown in FIG. 1 is the metal layer 301 where the integrated circuit die 302 is mounted thereon.

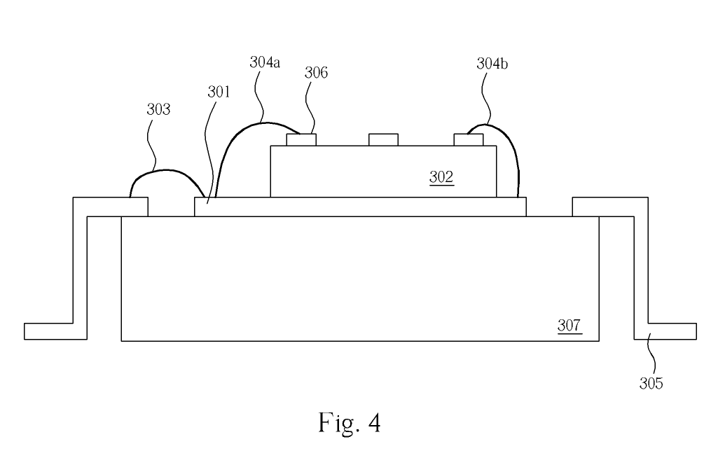

Please refer to FIG. 4, which is a side view of the integrated circuit package 300 shown in FIG. 3. The integrated circuit die 302 is stacked on the metal layer 301. Two bond pads 306 are connected to the metal layer 301 through bond wires 304a and 304b, respectively. As shown in FIG. 3 and FIG. 4, it is clear that a plurality of bond pads 306 of the integrated circuit die 302 are first connected to the metal layer 301 through bond wires 304a, 304b, and then shares a common bond wire 303 to reach a single lead 305. The metal layer 301 acts as a ground layer and is capable of reducing noise interference to improve signal quality and operating stability of the integrated circuit 300. In this embodiment, the metal layer 302 is a low impedance conductor for serving as the ground layer. In addition, the integrated circuit die 302 is formed on a p-substrate, and the p-substrate is directly mounted on the metal layer 301.

Please note that the bond pads connected to the bond wires 304a, 304b could respectively belong to logic blocks of different functions. In other words, the integrated circuit die 302 includes a plurality of functions, and a bond pad corresponding to each function of the integrated circuit die 302 is electrically connected to the metal layer 301 via a corresponding bond wire. Furthermore, in the above embodiment, the metal layer 301 is placed under the integrated circuit die 302. However, the metal layer 301 is not limited to loading the integrated circuit die 302. For instance, the metal layer 301 and the integrated circuit die 302 can be placed on the lead frame 307 side by side. The same objective of making a plurality of bond pads have a common lead is achieved.

In contrast to the prior art, the integrated circuit package of the present invention makes use of a metal layer to create a common interconnection ground area therein to reduce the unwanted noise interference. Due to the metal layer serving as a ground layer is disposed within the integrated circuit package, a printed circuit board can get rid of a ground layer originally formed thereon. In addition, the integrated circuit package requires only a single external ground pin, which saves the cost of forming pins used to connect a printed circuit board. Further, the cost of a printed circuit board is reduced because the integrated circuit package of the present invention can be applied to a single-layer printed circuit board.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An integrated circuit package, comprising:
a lead frame having a plurality of leads and a metal layer;
an integrated circuit die having a plurality of power-level bond pads;
a plurality of bond wires electrically connected between the power-level bond pads and the metal layer, respectively; and
wherein said metal layer is electrically connected to a lead of said lead fram.

2. The integrated circuit package of claim 1, wherein the integrated circuit die is mounted on the metal layer.

3. The integrated circuit package of claim 2, wherein the integrated circuit die is formed on a p-substrate, and the p-substrate is stuck on the metal layer.

4. The integrated circuit package of claim 1, wherein the metal layer is a low impedance conductor.

5. The integrated circuit package of claim 4, wherein the metal layer is formed by copper, silver, gold or aluminum.

6. The integrated circuit package of claim 1, wherein the metal layer is a power-ground layer, and the power-level bond pads are power-ground bond pads.

7. The integrated circuit package of claim 1, wherein the integrated circuit die includes a plurality of functions, and a plurality of power-level bond pads corresponding to each function of the integrated circuit die are electrically connected together with the metal layer via a bond wire.

8. A method of packaging an integrated circuit die, the integrated circuit die having a plurality of power-level bond pads, the method comprising:
providing a lead frame with a plurality of leads and a metal layer;
mounting the integrated circuit die on the lead frame;
electrically connecting the power-level bond pads to the metal layer, respectively; and
electrically connecting the metal layer to a lead of the lead frame.

9. The method of claim 8, wherein the step of mounting the integrated circuit die mounts the integrated circuit die on the metal layer.

10. The method of claim 9, wherein the integrated circuit die is formed on a p-substrate, and the step of mounting the integrated circuit die mounts the p-substrate on the metal layer.

11. The method of claim 8, wherein the metal layer is a low impedance conductor.

12. The method of claim 8, wherein the integrated circuit packaging is high immunity to electrically noise.

13. The method of claim 8, wherein the metal layer is a power-ground layer, and the power-level bond pads are power-ground bond pads.
